(19) United States
(12) Patent Application Publication
(10) Pub. No.: US 2010/0248165 A1
(43) Pub. Date: Sep. 30, 2010

(54) INFORMATION PROCESSING METHOD, EXPOSURE PROCESSING SYSTEM USING SAME, DEVICE MANUFACTURING METHOD, AND INFORMATION PROCESSING APPARATUS

(75) Inventors: Daisuke Itai, Yokohama-shi (JP); Kunitaka Ozawa, Utsunomiya-shi (JP); Hiroaki Fujiwara, Utsunomiya-shi (JP); Yoshihiro Kawauchi, Utsunomiya-shi (JP); Hisao Nakagawa, Utsunomiya-shi (JP); Hajime Nakamura, Hiratsuka-shi (JP); Mitsuhiro Masuda, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/730,843

(22) Filed: Mar. 24, 2010

(30) Foreign Application Priority Data
Mar. 26, 2009 (JP) 2009-076146

(51) Int. Cl. G03F 7/20; G06F 15/00; G03B 27/32

(52) U.S. Cl. 430/325; 702/182; 355/18

(57) ABSTRACT

The information processing method of the present invention is provided that specifies an extraction period for extracting apparatus data to be generated by an industrial apparatus and analyzes a state of the industrial apparatus based on the apparatus data having an occurrence time within the extraction period. The information processing method includes a period changing step of changing the extraction period so as to enable the apparatus data required for the analysis of the state to be included, when the apparatus data required for the analysis of the state is not included within the extraction period.

### BACKGROUND OF THE INVENTION

1. Field of the Invention

The present invention relates to an information processing method, an exposure processing system using the same, a device manufacturing method, an information processing apparatus, and an information processing program.

2. Description of the Related Art

An industrial apparatus such as a device manufacturing apparatus for manufacturing a semiconductor device exemplified by a semiconductor exposure apparatus generates massive apparatus information data such as processing start and end, error event, measurement results, or the like during a manufacturing process. The industrial apparatus performs anomaly detection, condition diagnosis, and analysis of the cause of the anomaly of the apparatus on the basis of these data.

In general, apparatus information to be generated by the industrial apparatus is recorded to a database together with occurrence time information. For the analysis of the state of the apparatus, a user specifies the extraction period of apparatus information so as to extract apparatus information having an occurrence time within the extraction period.

However, apparatus information required for the state analysis of the apparatus is not necessarily obtained entirely in a specified time range. For example, a semiconductor manufacturing apparatus performs processing for each lot, where one lot may include a plurality of wafers. The lot state analysis needs to be performed by using all events from the start to the end of processing and measurement results. The processing time for one lot normally takes several tens of minutes. If the state analysis of each lot is performed by extracting one day's worth of data, the day's first and last lot processing may overlap a day before or after the chosen date, whereby a portion of the lot processing information for these may not be extracted. Therefore, when a dropout from lot processing information is confirmed, a new period must be set so as to extract the information again, which requires a considerable time and labor. Moreover, although measures such as the excess extension of the extraction period are taken in order to prevent the dropout of lot processing information, the amount of information becomes larger, resulting in unnecessary additional time taken for the transmission and analysis of information.

Accordingly, as a method for acquiring information required for the error analysis, Japanese Patent Laid-Open No. 2005-72259 discloses an error processing method for recording information prior to an error occurrence based on a substrate processing apparatus to be adopted in an exposure apparatus. However, Japanese Patent Laid-Open No. 2005-72259 does not define how amount the information prior to an error occurrence should be recorded and thereby is not sufficient as the means for preventing the dropout of apparatus information or the creation of excess information.

### SUMMARY OF THE INVENTION

The present invention provides an information processing method for modifying the extraction period to an appropriate period such that no dropout of apparatus data required by a user occurs in the period specified by the user.

According to an aspect of the present invention, an information processing method that specifies an extraction period for extracting apparatus data to be generated by an industrial apparatus and analyzes a state of the industrial apparatus based on the apparatus data having an occurrence time within the extraction period, wherein the information processing method includes a period changing step of changing the extraction period so as to enable the apparatus data required for the analysis of the state to be included when the apparatus data required for the analysis of the state is not included within the extraction period.

According to the present invention, when apparatus data, which is necessary for condition diagnosis, analysis of the cause of the anomaly, or the like of an industrial apparatus, is extracted by specifying the extraction period, such apparatus data can be extracted without dropping out any apparatus data that is necessary even when outside the extraction period, resulting in an improvement in the operational efficiency.

Further features of the present invention will become apparent from the following description of exemplary embodiments with reference to the attached drawings.

### BRIEF DESCRIPTION OF THE DRAWINGS

FIG. 1 is a schematic diagram showing a configuration of an exposure apparatus according to an embodiment of the present invention.

FIG. 2 is a schematic diagram showing a configuration of an exposure processing system according to an embodiment of the present invention.

FIG. 3 shows an example of apparatus data accumulated in the database.

FIG. 4 is a flowchart showing an information processing method according to an embodiment of the present invention.

FIG. 5 is a flowchart showing an information processing method for determining the extraction start time.

FIG. 6 is a diagram showing the apparatus data to be extracted and the state in which the determination apparatus data is generated during the extraction period and the determination information extraction period according to the first embodiment of the present invention.

FIG. 7 is a flowchart showing an information processing method for determining the extraction end time.

### DESCRIPTION OF THE EMBODIMENTS

Hereinafter, preferred embodiments of the present invention will now be described with reference to the accompanying drawings.

### (Exposure Apparatus)

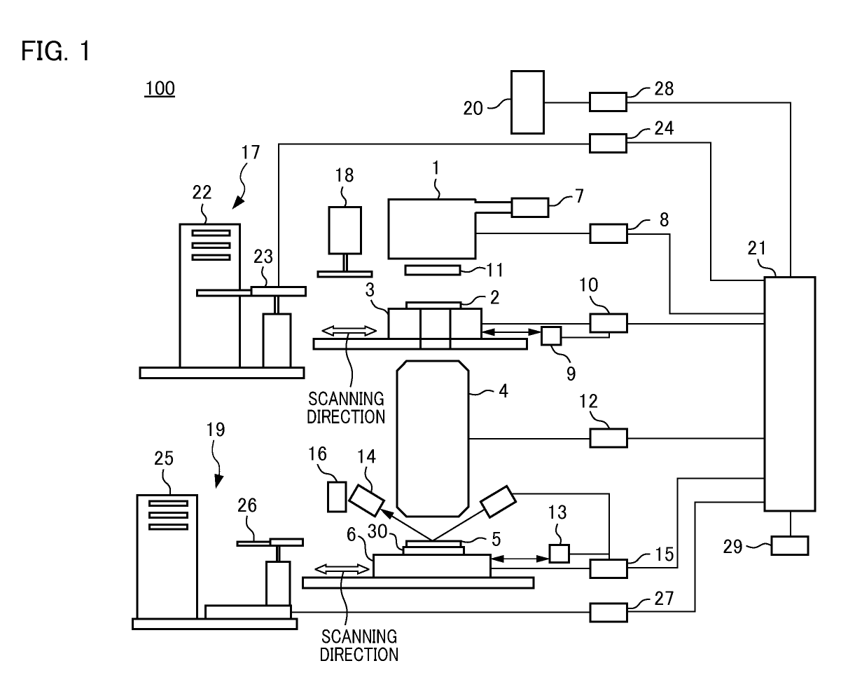

FIG. 1 is a schematic diagram showing a configuration of an exposure apparatus according to an embodiment of the present invention. Hereinafter, a description will be given of a case in which the exposure apparatus of the present invention is applied to a scanning type exposure apparatus for manufacturing a semiconductor device. For the purpose of explanation, in the following diagrams, the Z axis is aligned parallel to the optical axis of the projection optical system constituting the exposure apparatus, the Y axis is aligned in the scanning direction of a reticle (original) and a wafer (substrate) during scanning exposure in the plane perpendicular to the Z axis, and the X axis is aligned in the non-scanning direction perpendicular to the Y axis.

The exposure apparatus 100 first includes an illumination optical system 1, a reticle 2 on which an exposure pattern is formed, a reticle stage 3 on which the reticle 2 is placed, a projection optical system 4, a wafer 5 that is a substrate to be processed, and a wafer stage 6 on which the wafer 5 is placed.

The illumination optical system 1 is an apparatus that adjusts the shape and light intensity distribution of a light beam emitted from a light source 7 to illuminate the reticle 2. The illumination optical system 1 includes, for example, a plurality of aperture diaphragms having different circular aperture areas for setting a coherence factor (c), a ring-shaped diaphragm for annular illumination, a quadruple diaphragm, a mechanism for adjusting illumination light intensity (e.g., a plurality of ND filters and a mechanism for switching thereof), and the like. Furthermore, the illumination optical system 1 includes a light intensity detector for measuring light intensity, a slit for determining the shape of a light beam, a blind that ensures the illumination range and is disposed at a position conjugate with the reticle 2, a drive mechanism for driving the blind, and the like. Note that the illumination optical system 1 and the light source 7 are controlled by commands from an illumination optical system control system 8.

The reticle stage 3 is a stage apparatus that is movable in two axial directions (the X and Y directions) orthogonal to each other within a plane orthogonal to the optical axis while the reticle 2 is placed and held thereon. Note that the X- and Y-directional positions of the reticle stage 3 and the rotation around the axis in the X and Y directions are measured by a reticle stage measuring system 9. The reticle stage 3 is controlled by commands from the reticle stage control system 10 based on the information provided from the reticle stage measuring system 9.

Furthermore, a TTR (Through The Reticle) observation optical system 11 is provided between the illumination optical system 1 and the reticle stage 3. The TTR observation optical system 11 is an observation optical system in which a method capable of observing and simultaneously measuring a mark on the reticle 2 or a stage reference mark disposed on the reticle stage 3 and a stage reference mark on the wafer stage 6 via the projection optical system 4 is adopted. The TTR observation optical system 11 measures the positions of the reticle 2, the reticle stage 3, and the wafer stage 6 in three directions, that is, the X, Y, and Z directions, and the rotation around the axis in the three X, Y, and Z directions.

The projection optical system 4 is an apparatus for projecting the pattern of the reticle 2 onto the wafer 5 at a predetermined reduction scale (e.g., 4:1). The projection optical system 4 includes a numerical aperture setting mechanism for setting the numerical aperture, a lens drive mechanism for correcting aberration, and the like. Note that the projection optical system 4 is controlled by commands from the projection optical system control system 12.

The wafer stage 6 is a stage apparatus that is movable to the optical axis direction (the Z direction) of the projection optical system 4 and two axial directions (the X and Y directions) orthogonal to each other within a plane orthogonal to the optical axis while the reticle 2 is placed and held thereon. Note that the position of the wafer 5 is measured by a wafer stage measurement system 13 and an alignment measurement system 14. In this case, the wafer stage measurement system 13 measures, for example, the positions in the X, Y, and Z directions, and the rotation around the axis in the X, Y, and Z directions. Also, the alignment measurement system 14 measures the surface position of the wafer 5 in the Z direction. The wafer stage 6 is controlled by commands from the wafer stage control system 15 based on the information provided from the wafer stage measurement system 13 and the alignment measurement system 14.

Furthermore, an off-axis observation optical system 16, which is capable of observing and measuring the surface of the wafer 5 with non-exposure light, is provided near the wafer stage 6. The off-axis observation optical system 16 is an apparatus that observes a plurality of marks disposed on the wafer 5, and measures the position and shape of the pattern formed on the wafer 5 so that the pattern of the reticle 2 can be transferred in alignment with the position of the pattern formed on the wafer 5. The off-axis observation optical system 16 can also observe the stage reference mark on the wafer stage 6 to measure the position of the stage reference mark.

In addition, the exposure apparatus 100 includes a reticle conveyance unit 17, a reticle alignment unit 18, a wafer conveyance unit 19, a chamber 20, and a main control system 21.

The reticle conveyance unit 17 is a conveyance system for conveying the reticle 2, which is configured with a reticle library 22, a reticle robot 23, and the like. Also, the reticle alignment unit 18 is an apparatus for aligning the position of the reticle 2 with the mark on the reticle stage 3. Note that the reticle conveyance unit 17 is controlled by commands from a reticle conveyance control system 24. In addition, the wafer conveyance unit 19 is a conveyance system for conveying the wafer 5, which is configured with a wafer cassette elevator 25, a wafer loading/unloading robot 26, and the like. Note that the wafer conveyance unit 19 is controlled by the command from a wafer conveyance control system 27. Furthermore, the chamber 20 is a hollow apparatus that mainly performs an air temperature adjustment and air cleaning for filtering minute foreign matter so as to maintain the internal environmental temperature of the exposure apparatus 100. Note that the chamber 20 is controlled by commands from a chamber control system 28.

The main control system 21 controls constituent control systems of the exposure apparatus 100, such as the illumination optical system control system 8, the reticle stage control system 10, the projection optical system control system 12, the wafer stage control system 15, the reticle conveyance control system 24, the wafer conveyance control system 27, the chamber control system 28, and the like. The main control system 21 can acquire setting parameters or operation commands, which define the exposure operation of the exposure apparatus 100, via a communication interface 29 so as to control each constituent component of the exposure apparatus 100 based on the information thereof. Also, the main control system 21 has a function of transmitting the above setting parameters and operation commands, as well as information concerning the operation state, operation result, measurement result, error event, and the like, and information concerning the occurrence time of these to an external storage apparatus 150 to be described below via the communication interface 29.

Next, an operation of scanning exposure processing performed by the exposure apparatus 100 will be described.

The shape and light intensity distribution of the light beam emitted from the light source 7 is adjusted by the illumination optical system 1 so as to illuminate the reticle 2 which is placed on the reticle stage 3. The pattern of the reticle 2 is transferred to a predetermined exposure range (shot region) on the wafer 5 on which a photosensitizing agent (resist) is applied and which is suction-held to a wafer adsorption chuck 30 on the wafer stage 6 via the projection optical system 4. In this manner, a latent image pattern is formed on the photosensitizing agent coated on the wafer 5. Exposure processing (transfer processing) is performed for each shot which is arranged on the wafer 5, whereby the latent image pattern is formed on the entire surface of the wafer 5. The latent image pattern is developed in a separate developing step to thereby form a mask pattern (resist pattern).

In the exposure processing, in order to transfer the entire pattern range of the reticle 2 to the shot region arranged on the wafer 5 by means of a slit-like illumination light beam, the reticle stage 3 is driven in the “scanning direction” shown in FIG. 1. At the same time, the wafer stage 6 is also driven in the “scanning direction” shown in FIG. 1. In this case, the reticle stage 3 and the wafer stage 6 are driven at a speed ratio matching the projection magnification of the projection optical system 4. Here, if the relative position between the reticle 2 and the wafer 5 shifts, a deformed pattern is transferred onto the shot region on the wafer 5. To avoid this situation, the main control system 21 calculates the relative positional shift between the reticle 2 and the wafer 5, and controls the reticle stage control system 10 and the wafer stage control system 15 so that the relative positional shift becomes zero.

Also, exposure processing is executed based on setting parameters (JOB parameters) which define the exposure operation of the exposure apparatus 100. Exemplary JOB parameters include a step name (job name), an ID for identify a lot, a shot region position, a shot region range (dimension of region), a shot region arrangement, each shot region number, an exposure amount, an exposure scanning speed, an exposure scanning direction, and the like. Furthermore, JOB parameters include calibration items for a unit constituting the exposure apparatus, the timing of implementing calibration measurement and the number of measurements, an alignment method for a wafer and shot, the number of sample shots for alignment measurement and the number of measurements, and the like.

At this time, the main control system 21 controls constituent control systems of the exposure apparatus 100 for each lot base on the JOB parameters, where one lot may include one wafer or a plurality of wafers, so as to perform exposure processing. More specifically, first, in accordance with the start of lot processing, the reticle 2 and the wafer 5 for use in exposure processing are supplied into the exposure apparatus 100. When the supply of the reticle 2 and the wafer 5 is completed, calibration of the unit, specified by the JOB parameter, among the constituent elements of the exposure apparatus 100 and alignment of the reticle 2 and the wafer 5 are performed. The main control system 21 performs compensated driving of each unit, the reticle 2, and the wafer 5, respectively, based on the information result, so that each shot region on the wafer 5 is exposed by a step and scan scheme.

In the exposure processing information such as the start and end of the processing operation of each unit, a set value with respect to processing, each measurement value for calibration and alignment, shot exposure amount results, scan operation control results, an event such as an error occurring in the apparatus, and the occurrence time thereof is generated. Hereinafter, the information is defined as “apparatus-generated information” because it is generated by the processing operation of the exposure apparatus. Since the exposure processing is performed for each lot by the JOB parameters, the exposure processing can be identified with the process-defined job name and the processed ID for identify a lot. Furthermore, wafer and shot processing can be identified with a wafer number, shot number, and ID for identify a die. The main control system 21 adds attribute information such as a job name, ID for identify a lot, wafer number, shot number, ID for identify a die, or the like to apparatus information such as processing, event, measurement results, and occurrence time so as to transmit such information to the external storage apparatus 150.

### (Exposure Processing System)

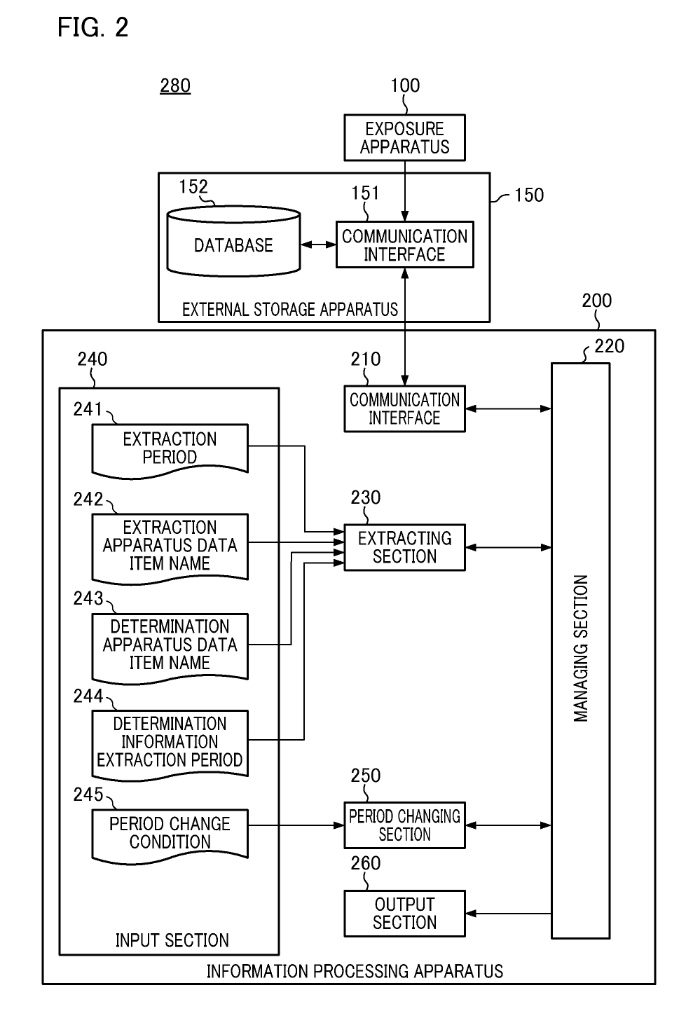

Next, an exposure processing system according to an embodiment of the present invention will be described. FIG. 2 is a schematic diagram showing a configuration of an exposure processing system. An exposure processing system 280 includes the above-described exposure apparatus 100, the external storage apparatus 150, and an information processing apparatus 200. Each of the constituent apparatuses of the exposure processing system 280 is interconnected via a communication interface.

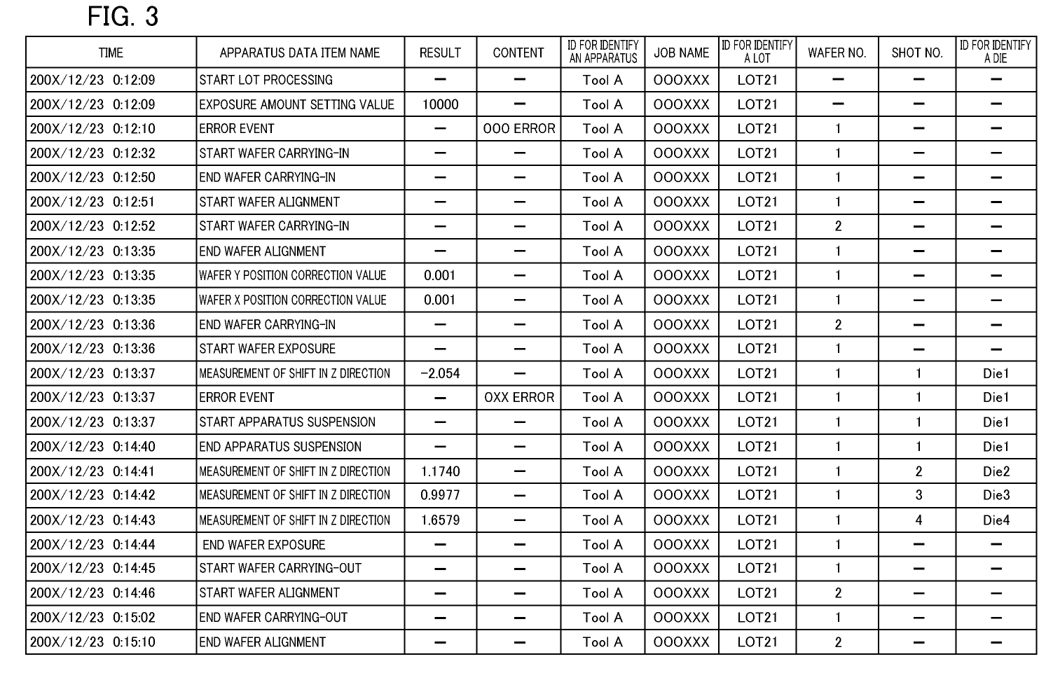

The external storage apparatus 150 is an apparatus that collects apparatus data shown in FIG. 3 from the exposure apparatus 100 via a communication interface 151 and stores the apparatus data in a database 152. FIG. 3 shows an example of apparatus data. Apparatus data consists of apparatus-generated information such as setting parameters for defining the exposure operation, the start and end of the processing operations, operation results, measurement results, events such as an error, and the occurrence time thereof, and attribute information such as a job name, ID for identify a lot, wafer number, shot number, ID for identify a die, or the like.

The information processing apparatus 200 is an apparatus including an information processing program having a function of extracting data as appropriate from the apparatus information stored in the external storage apparatus 150 via a the communication interface 210 and processing the data. The information processing apparatus 200 is configured, for example, by installing an information processing program on a general purpose computer. By the information processing program being installed on the information processing apparatus 200, the information processing apparatus 200 operates as an apparatus including an extracting section 230 and a period changing section 250. Alternatively, the information processing apparatus 200 operates as an apparatus for executing an extracting unit, a period changing unit, and the like. While in the present embodiment the information processing apparatus 200 is disposed at a position different from that of the exposure apparatus 100, the information processing apparatus 200 may be disposed in the interior of the exposure apparatus 100.

The information processing apparatus 200 includes a communication interface 210, a managing section 220, the extracting section 230, an input section 240, the period changing section 250, and an output section 260. The managing section 220 is a processing section that manages (controls) the communication interface 210, the extracting section 230, the input section 240, the period changing section 250, and the output section 260. The extracting section 230 is a processing section that extracts the specified apparatus data during the specified period from the apparatus data that is stored in the database 152 in the external storage apparatus 150. The input section 240 is a processing section that inputs various conditions required for information processing into the extracting section 230 and the period changing section 250. The input section 240 includes an extraction period 241, an extraction apparatus data item name 242, a determination apparatus data item name 243, and a determination information extraction period 244 as the input condition to the extracting section 230. The input section 240 further includes a period change condition 245 as the input condition to the period changing section 250. The period changing section 250 is a processing section that determines a change of the extraction period 241 so as to determine a new extraction period. At this time, the period changing section 250 specifies the first information as the determination apparatus data item name 243 and the second information to pair with the first information, and further specifies a time span as the determination information extraction period 244 for the determination of any extraction period change. In this manner, the extracting section 230 extracts apparatus data corresponding to the determination apparatus data item name 243 over the extraction period plus a range of the time span. The period changing section 250 determines before and after the start or end of the extraction period whether or not a period change is required depending on the timing of occurrence of these two periods. Here, a determination condition for determining whether the extraction period is shortened or prolonged is specified by the period change condition 245, and the period changing section 250 sets the time of occurrence of the first information or the second information as the start time or the end time of the extraction period based on the specification given by the period change condition 245. Furthermore, the output section 260 is a processing section that outputs apparatus data that has been extracted during the changed period.

### First Embodiment of Information Processing Method

Next, an information processing method for changing a period specified for information extraction to an appropriate period such that the required information is included based on apparatus data stored in the database 152 will be described. In the present embodiment, a description will be made assuming the case where apparatus data relating to a lot processed in a day is extracted.

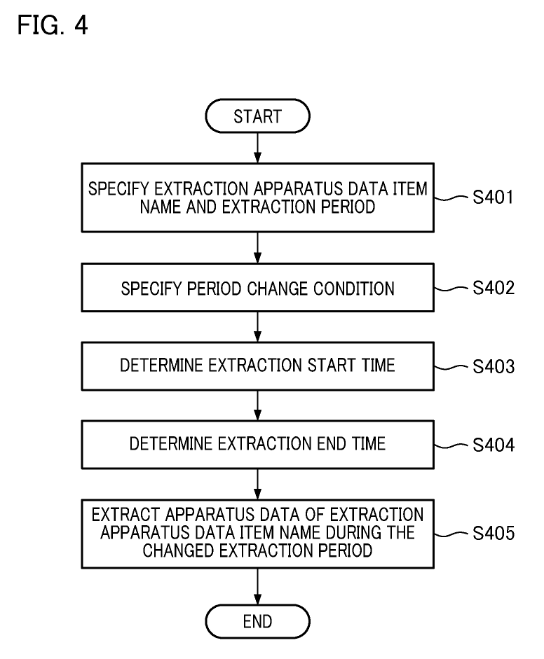

FIG. 4 is a flowchart showing an example of an information processing method according to a first embodiment of the present invention. First, in order to extract necessary apparatus data from the database 152, a user specifies the extraction period 241 for extracting information and the extraction apparatus data item name 242 by means of the input section 240 (step S401). It is assumed that the extraction apparatus data item name to be specified is an event such as the start and end of each processing operation, operation results, measurement results, errors, and the like as shown in FIG. 3. It is also assumed that the extraction period 241 is, for example, from the time of 00:00 at a predetermined day to less than the time of 24:00.

Next, as a condition for determining an extraction period change, a user specifies the determination apparatus data item name 243, the determination information extraction period 244, and the period change condition 245 by means of the input section 240 (step S402). Here, the determination apparatus data item name 243 specifies the first information and the second information. For example, since apparatus data during lot processing is required in the present embodiment, the first information and the second information specify either the lot processing start or the lot processing end.

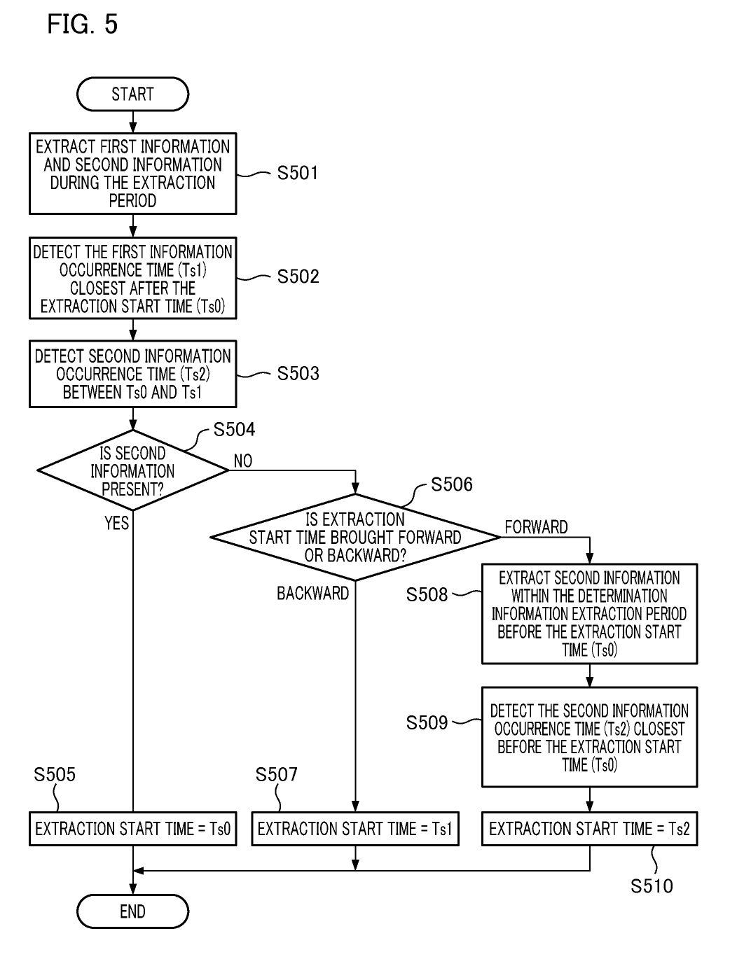

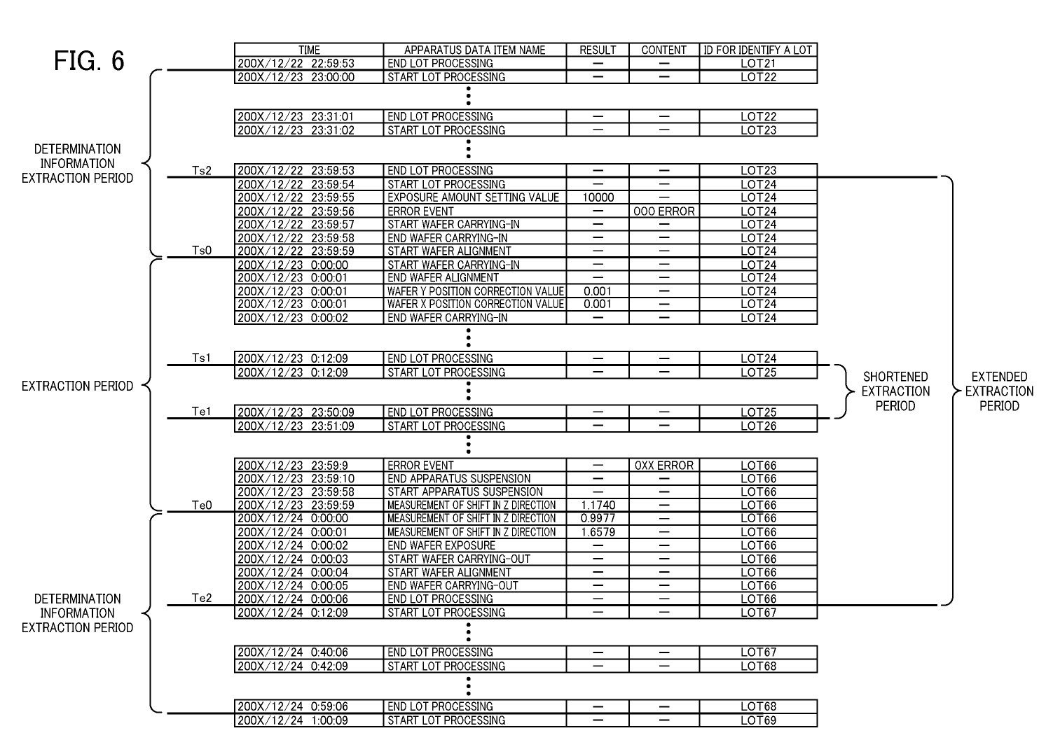

Next, the period changing section 250 determines the extraction start time (period changing step in step S403). Determination processing of the extraction start time will be described with reference to FIGS. 5 and 6. FIG. 5 is a flowchart explaining the flow of determination processing of the extraction start time. FIG. 6 is a list of a time series containing the apparatus data to be extracted and the occurring state of the determination apparatus data during the extraction period and the determination information extraction period.

First, the extracting section 230 extracts apparatus data corresponding to the determination apparatus data item name 243 of the first information and the second information during the extraction period from the database 152 (step S501). Next, the period changing section 250 detects the closest first information after the extraction start time Ts0 defined during the extraction period 241, and identifies the occurrence time as Ts1 (step S502). Next, the period changing section 250 detects the second information within a time period from the extraction start time Ts0 to the first information occurrence time Ts1 (step S503). Here, if the second information has not been detected within the time period, the extraction start time is changed (step S504). On the other hand, if the second information has been detected, the extraction start time is not changed (step S505). It is assumed in the present embodiment that the first information is the lot processing end and the second information is the lot processing start as the determination apparatus data item of the extraction start time change. In other words, if apparatus data (the first information) of the lot processing end closest to the extraction start time Ts0 is detected and the lot processing start (the second information) is not initiated from the extraction start time Ts0 to the lot processing end time Ts1, the extraction start time is to be changed. Next, if the extraction start time has been changed, the period changing section 250 determines whether the start time is moved forward or backward (step S506). For determining forward or backward movement of the start time, reference is made to the period change condition 245 specified by a user. Here, if the start time is moved backward, the first information occurrence time Ts1 becomes the extraction start time (step S507). On the other hand, if the start time is moved forward, the extracting section 230 extracts the second information from the database 152 in the range of the time span that has been specified as the determination information extraction period 244 before the extraction start time Ts0 (step S508). The period changing section 250 detects the second information occurrence time Ts2 closest to the extraction start time Ts0 (step S509), whereby the second information occurrence time Ts2 becomes the extraction start time (step S510).

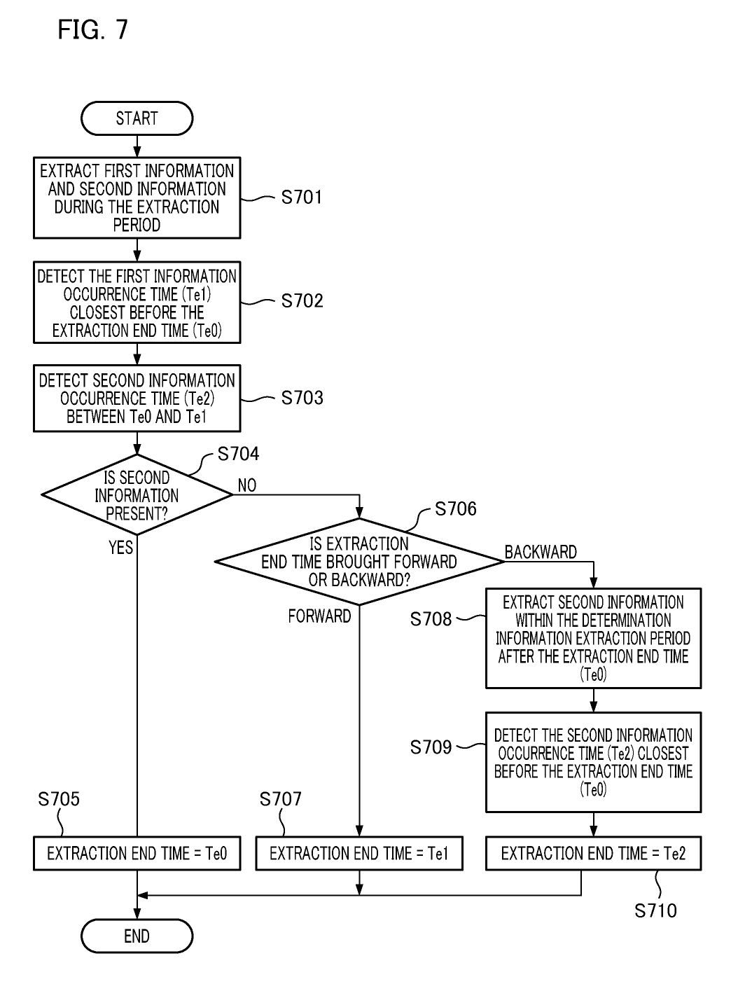

Next, the period changing section 250 determines the extraction end time (period changing step in step S404). Determination processing of the extraction end time will be described with reference to FIGS. 6 and 7. FIG. 7 is a flowchart explaining the flow of determination processing of the extraction end time.

First, the extracting section 230 extracts apparatus data corresponding to the determination apparatus data item name 243 of the first information and the second information during the extraction period from the database 152 (step S701). At this time, apparatus data that has been extracted in step S501 of FIG. 5 may be used as apparatus data. Next, the period changing section 250 detects the closest first information before the extraction end time Te0 defined during the extraction period 241, and identifies the occurrence time as Te1 (step S702). Next, the period changing section 250 detects the second information within a time period from the extraction end time Te0 to the first information occurrence time Te1 (step S703). Here, if the second information has not been detected within the time period, the extraction end time is changed (step S704). On the other hand, if the second information has been detected, the extraction end time is not changed (step S705). It is assumed in the present embodiment that the first information is the lot processing start and the second information is the lot processing end, which serves as the determination apparatus data item of the extraction end time change. In other words, if apparatus data (the first information) of the lot processing start closest to the extraction end time Te0 is detected and the lot processing end (the second information) is not initiated from the extraction end time Te0 to the lot processing start time Te1, the extraction end time is to be changed. Next, if the extraction end time has been changed, the period changing section 250 determines whether the end time is moved forward or backward (step S706). For determining the forward or backward movement of the end time, reference is made to the period change condition 245 specified by a user. Here, if the end time is moved forward, the first information occurrence time Te1 becomes the extraction end time (step S707). On the other hand, if the end time is moved backward, the extracting section 230 extracts the second information from the database 152 in the range of the time span that has been specified as the determination information extraction period 244 after the extraction end time Te0 (step S708). The period changing section 250 detects the second information occurrence time Ts2 closest to the extraction end time Te0 (step S709), whereby the second information occurrence time Te2 becomes the extraction end time (step S710).

Then, the extracting section 230 extracts the information of the specified extraction apparatus data item name from the database 152 based on the new extraction period that has been determined by the period changing section 250, the output section 260 outputs the information, and processing is terminated (step S405).

In steps S509 and S709, if the second information has not been detected within the range of the determination information extraction period, processing can also be returned to step S508 and S708, respectively, so as to carry out extraction of the second information either before the previous determination information extraction period or at the subsequent determination information extraction period. The number of times such extraction processing is repeated may be specified. At this time, if the second information cannot be detected at the last determination information extraction period of the specified number of periods, the extraction period is to be changed up to the last determination information extraction period.

While in the present embodiment, apparatus-generated information is specified as determination information item, attribute information may also be added. In this case, the attribute information may be added to the detection condition of the second information by using the attribute information of the information detected as the closest the first information, which has been detected at the start time or the end time of the extraction period, as a condition. In this manner, for example, in an apparatus in which a plurality of lots is processed in parallel, the start and the end of other lot subjected to parallel processing can be distinguished when the first information denotes the lot processing start or the second information denotes the lot processing end.

As can be understood from the description above, in accordance with the present invention, apparatus data that is necessary for condition diagnosis, analysis of the cause of an anomaly, or the like of an industrial apparatus such as an exposure apparatus can be extracted without dropping out any apparatus data that is necessary even if the extraction period lies outside, resulting in an improvement in the operational efficiency. Therefore, even under circumstances where the dropout of any information data may occur, time and effort for resetting a new extraction period so as to extract information again can be eliminated. In addition, there is no need to take measures such as an excess extension of the extraction period to prevent the dropout of any apparatus data, whereby the problem of the additional time required for the transmission and analysis of information is solved.

### Second Embodiment of Information Processing Method

Next, an information processing method according to a second embodiment of the present invention will be described. The feature of the present embodiment resides in that, in the first embodiment, there is only one second information to pair with the first information whereas, in the second embodiment, a plurality of the second information is specified.

First, as an example of change determination of the extraction start time, a description will be given in the case where apparatus data that is necessary for analysis of the cause of a failure, which requires resetting of the apparatus, occurred in a single day of the extraction period is extracted. The information processing apparatus 200 detects a product signal for resetting an apparatus, and performs cause analysis based on, for example, the previously processed lot, wafer, or event prior to the occurrence of the apparatus reset occurred during processing in the apparatus reset sequence, processing result, and measurement result. In this case, a user assigns apparatus reset processing start information to the first information as the determination apparatus data item name, and also assigns a plurality of apparatus data item names showing the start of each processing such as lot processing start, wafer processing start, reset processing start, or the like to the second information. In this manner, the period changing section 250 detects apparatus reset processing start information (the first information) closest to the extraction start time Ts0, and changes the extraction start time if there is no the second information between the extraction start time Ts0 and the apparatus reset processing the start time Ts1.

On the other hand, while in the first embodiment, the lot processing start is set as the first information and the lot processing end is set as the second information as an example of change determination of the extraction end time, a description will be given in the case where the resetting of the apparatus occurs during lot processing because of a failure due to an abnormal completion of lot processing. In this case, a user assigns the lot processing end and the apparatus reset processing start to the second information if the lot processing end is not recorded as apparatus data.

### Third Embodiment of Information Processing Method

Next, an information processing method according to a third embodiment of the present invention will be described. The feature of the present embodiment resides in that, in the first and second embodiments, the change of the extraction period is determined on the basis of one of the first information whereas, in the third embodiment, the change of the extraction period is determined on the basis of a plurality of the first information. In other words, in the first embodiment, the aim is to provide an analysis of the content of lot processing for one day. In the second embodiment, the aim is to provide analysis of the cause of a failure, which requires resetting of the apparatus, occurred in a single day. In contrast, in the present embodiment, the period changing section 250 performs the change of the extraction period in a method in combination with the first embodiment and the second embodiment when the apparatus state in one day is analyzed. In this case, a user assigns the determination apparatus data item name specified in the first and the second embodiments to the first information. In this manner, the extracting section 230 can extract apparatus data without dropping out any apparatus data during either lot processing or reset processing.

### (Device Manufacturing Method)

Next, a method of manufacturing a device (semiconductor device, liquid crystal display device, etc.) as an embodiment of the present invention is described. The semiconductor device is manufactured through a front-end process in which an integrated circuit is formed on a wafer, and a back-end process in which an integrated circuit chip is completed as a product from the integrated circuit on the wafer formed in the front-end process. The front-end process includes a step of exposing a wafer coated with a photoresist to light using the above-described exposure apparatus of the present invention, and a step of developing the exposed wafer. The back-end process includes an assembly step (dicing and bonding), and a packaging step (sealing). The liquid crystal display device is manufactured through a process in which a transparent electrode is formed. The process of forming a plurality of transparent electrodes includes a step of coating a glass substrate with a transparent conductive film deposited thereon with a photoresist, a step of exposing the glass substrate coated with the photoresist thereon to light using the above-described exposure apparatus, and a step of developing the exposed glass substrate. The device manufacturing method of this embodiment has an advantage, as compared with a conventional device manufacturing method, in at least one of performance, quality, productivity and production cost of a device.

While the embodiments of the present invention have been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2009-076146 filed Mar. 26, 2009 which is hereby incorporated by reference herein in its entirety.

What is claimed is:

1. An information processing method that specifies an extraction period for extracting apparatus data to be generated by an industrial apparatus and analyzes a state of the industrial apparatus based on the apparatus data having an occurrence time within the extraction period, the information processing method comprising:
a period changing step of changing the extraction period so as to enable the apparatus data required for the analysis of the state to be included, when the apparatus data required for the analysis of the state is not included within the extraction period.

2. The information processing method according to claim 1, further comprising:
an extracting step of extracting the apparatus data required for the analysis of the state from the apparatus data to be generated by the industrial apparatus within the extraction period,
wherein the extracting step further extracts the first information and the second information to pair with the first information, and the period changing step changes the extraction period based on a start time or a end time of the extraction period and the occurrence time of the first information and the second information.

3. The information processing method according to claim 2, wherein the period changing step determines the change of the start time when the second information is not present between the start time of the extraction period and the first information closest thereafter,
wherein the period changing step changes the start time to the occurrence time of the closest first information after the start time when a period change condition for delaying the start time in advance is set, and
wherein, on the other hand, the extracting step newly extracts the second information within an certain interval of time from the start time when the period change condition for advancing the start time in advance is set, and the period changing step changes the start time to the occurrence time of the second information closest before the start time.

4. The information processing method according to claim 2, wherein the period changing step determines the change of the end time when the second information is not present between the end time of the extraction period and the first information closest therebefore,
wherein the period changing step changes the end time to the occurrence time of the closest first information before the end time when the period change condition for advancing the end time in advance is set, and
wherein, on the other hand, the extracting step newly extracts the second information within a certain interval of time from the end time when the period change condition for delaying the end time in advance is set, and the period changing step changes the end time to the occurrence time of the second information closest after the end time.

5. The information processing method according to claim 1, wherein the industrial apparatus is an exposure apparatus.

6. An exposure processing system comprising an exposure apparatus, wherein when exposure processing is performed by the exposure apparatus, the information processing method according to claim 1 is employed.

7. A device manufacturing method comprising the steps of:
exposing a substrate by using the exposure processing system according to claim 6; and
developing the substrate.

8. An information processing apparatus that specifies an extraction period for extracting apparatus data to be generated by an industrial apparatus and analyzes a state of the industrial apparatus based on the apparatus data having an occurrence time within the extraction period, the information processing apparatus comprising:
a period changing section that changes the extraction period so as to enable the apparatus data required for the analysis of the state to be included, when the apparatus data required for the analysis of the state is not included within the extraction period.
